(19) United States
(12) Patent Application Publication
(10) Pub. No.: US 2007/0210304 A1
(43) Pub. Date: Sep. 13, 2007

(54) Nitride semiconductor single crystal film

(75) Inventors: Jun Komiyama, Hadano-shi (JP); Yoshihisa Abe, Sagamihara-shi (JP); Shunichi Suzuki, Hadano-shi (JP); Hideo Nakanishi, Hadano-shi (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 11/714,259

(22) Filed: Mar. 6, 2007

(30) Foreign Application Priority Data
Mar. 10, 2006 (JP) 2006-065081
Dec. 26, 2006 (JP) 2006-349128

(51) Int. Cl. H01L 29/08

(52) U.S. Cl. 257/40

(57) ABSTRACT

The present invention provides a nitride semiconductor single crystal including gallium nitride (GaN) or aluminum nitride (AlN) which are formed as a film to have good crystallinity without forming a 3C—SiC layer on a Si substrate, and which can be used suitably for a light emitting diode, a laser light emitting element, an electronic element that can be operated at a high speed and a high temperature, etc., as well as a high frequency device.

A GaN (0001) or AlN (0001) single crystal film, or a super-lattice structure of GaN (0001) and AlN (0001) is formed on a Si (110) substrate via a 2H—AlN buffer layer.

### BACKGROUND OF THE INVENTION

1. Field of the Invention

The present invention relates to a nitride semiconductor single crystal including gallium nitride (GaN) and/or aluminum nitride (AlN) which are used suitably for a light emitting diode, a laser diode, an electronic diode that can be operated at a high temperature, and can be handled at high power and high frequencies.

2. Description of the Related Art

A nitride semiconductor represented by GaN and AlN has a wide band gap and is expected to be a material applicable to a light emitting diode, a laser diode, an electronic diode that can be operated at a high speed and a high temperature, as a wide band gap semiconductor having outstanding characteristics, such as higher electric breakdown field and larger saturated drift velocity of electrons, etc.

Since the above-mentioned nitride semiconductor has a high melting point and equilibrium vapor pressure of nitrogen is very high, bulk crystal growth from the melt is difficult. For this reason, a single crystal is produced by heteroepitaxial growth on various single crystal substrates.

For example, a single crystal film of GaN (0001) or AlN (0001) is grown on several substrates, such as sapphire (0001), 6H—SiC (0001), Si (111), and so on through a various buffer layer.

Among the substrates used conventionally, as compared with Si substrates, large diameter sapphire (0001) and 6H—SiC (0001) are difficult to manufacture and their costs are high. For these reasons, as a substrate for growing a film of a nitride semiconductor single crystal, it is preferable to use the Si substrate from viewpoints of low cost manufacturing.

Further, since growth of the nitride semiconductor film on the Si substrate is possible to utilize present silicon technologies, utilization of this technique is very promising.

However, in the case of nitride films grown on the Si substrate, since cracks are formed in the nitride films due to a difference of thermal expansion coefficient between Si and nitride films and many crystal defects generate because of a difference of lattice constant between Si and nitride films, it has been difficult to grow a single crystal film having a thickness of one μm or more.

For this reason, it is necessary to use a suitable buffer layer for growing nitride films.

As an example such a buffer layer, it is proposed to employ a 3C—SiC (111) layer.

Conventionally, in order to correspond with a hexagonal crystal of GaN or AlN (wurtzite crystals), a Si (111) substrate is used for growing 3C—SiC (111) layer as a buffer layer. However, cracks are often generated on the Si (111) substrate, when the 3C—SiC (111) layer is grown as a film having a thickness of one μm or more.

In order to solve such a problem, it is developed that when the 3C—SiC (111) is grown on a Si (110) substrate, lattice mismatch between Si and 3C—SiC is more reduced than using the Si (111) substrate, thus improving crystallinity of the 3C—SiC (111) (for example, see Japanese Patent Publication (KOKAI) No. 2005-223206).

Additionally, in a high frequency device, if its operational frequency is high, an eddy current generates in the substrate and then Joule heat leads to trouble with device operation, so that an insulating substrate is required.

On the other hand, since 3C—SiC employed as the buffer layer has electric conductivity, the substrate with the 3C—SiC layer is unsuitable as the high frequency device.

Then, in an effort to grow the nitride single crystalline films on the Si substrate without the 3C—SiC layer, the present inventors repeated investigation and, as a result, have found that a single crystal film of GaN (0001) or AlN (0001) can be grown with a thickness of one μm or more by using the Si (110) substrate.

### SUMMARY OF THE INVENTION

The present invention aims to provide a nitride semiconductor single crystal which includes AlN or GaN is grown on a Si substrate, without a 3C—SiC layer, and which can be used suitably also for a high frequency device.

The nitride semiconductor single crystal in accordance with the present invention is characterized by being grown through a 2H—AlN buffer layer on a Si (110) substrate, and having GaN (0001) or AlN (0001).

According to the above-mentioned structure, the nitride semiconductor single crystal having good crystallinity can be grown without the 3C—SiC layer on the Si substrate.

Further, the nitride semiconductor single crystal of another preferred embodiment in accordance with the present invention is characterized by being grown through the 2H—AlN buffer layer on the Si (110) substrate, and having a super-lattice structure of GaN (0001) and AlN (0001).

Thus, the crystallinity of the nitride semiconductor single crystal can be further improved by forming the super-lattice structure of GaN and AlN.

As described above, according to the present invention, the single crystal film of GaN or AlN having good crystallinity can be obtained with a thickness of one μm or more without the 3C—SiC layer on the Si substrate.

Further, the crystallinity of the nitride semiconductor single crystal can be further improved by forming the super-lattice structure of GaN and AlN.

Therefore, the nitride semiconductor single crystal in accordance with the present invention can be used suitably for a light emitting diode, a laser diode, and an electronic diode that can be operated at a high temperature, as well as a high frequency device, thus improving element functions of these.

### BRIEF DESCRIPTION OF THE DRAWINGS

FIG. 1 shows a spectrum measured by θ-2θ scan of X ray diffraction for a 2H—AlN buffer layer grown on a Si (110) substrate.

FIG. 2 shows a spectrum measured by φ scan of X ray diffraction for the 2H—AlN buffer layer grown on the Si (110) substrate.

FIG. 3 shows spectra measured by ω scan of X ray diffraction for the 2H—AlN buffer layers grown on the Si (110) substrate and a Si (111) substrate.

FIG. 4 shows a spectrum measured by θ-2θ scan of X ray diffraction for a GaN single crystal layer (Example 1) grown through the 2H—AlN buffer layer on the Si (110) substrate.

### DESCRIPTION OF THE PREFERRED EMBODIMENTS

Hereafter, the present invention will be described in detail.

A nitride semiconductor single crystal in accordance with the present invention is a GaN single crystal or an AlN single crystal grown through a 2H—AlN buffer layer on a Si single crystal substrate.

This nitride semiconductor single crystal is grown on the Si substrate without a 3C—SiC layer, and its crystalline can also be improved as compared with that of conventional one.

Further, it also has an advantage that since it is grown on the Si substrate, an apparatus and technology which are used in a conventional Si semiconductor manufacture process can be used, and the Si substrates can be obtained with a large diameter at low cost.

As for the Si single crystal substrate used in the present invention, its manufacture method is not limited in particular. It may be manufactured by Czochralski (CZ) method, or may be manufactured by floating zone (FZ) method. Further, the Si single crystal layer may be grown epitaxially to these Si single crystal substrates by vapor-phase growth (Si epitaxial substrate).

Further, from a viewpoint of reduction in crystal lattice mismatch for the buffer layer and a nitride semiconductor single crystal film which is grown on the above-mentioned Si single crystal substrate, a Si (110) substrate is used for it instead of a conventionally used Si (111) substrate.

On the above-mentioned Si single crystal substrate, the 2H—AlN layer is grown as the buffer layer.

Instead of the conventional 3C—SiC layer, the 2H—AlN layer make it possible to be electric insulation of the substrate. Thus, the nitride semiconductor single crystal grown on the above mentioned layer is suitable for a high frequency device.

Further, the above-mentioned buffer layer covers the Si single crystal substrate surface and thus also serves to prevent the Si surface from etching or nitrization when the substrate is heated at a high temperature in order to grow the nitride semiconductor single crystal.

In terms of manufacturing costs, although the thickness of the above-mentioned AlN layer is preferable as thin as possible, the AlN layer is grown with the thickness which make it possible to reduce the crystal lattice mismatch between the Si (110) substrate and GaN (0001) or AlN (0001). In particular, it is preferable that the thickness is approximately 10-500 nm.

The above-mentioned AlN layer can be grown epitaxially on the above-mentioned the Si (110) substrate, for example, by vapor-phase growth.

These nitride semiconductor single crystals can be grown with the thickness of one μm or more by epitaxial growth of GaN (0001) or the AlN (0001) on the above-mentioned AlN layer.

Furthermore, GaN (0001) and AlN (0001) are alternately stacked as a thin film on the above-mentioned AlN layer to form a super-lattice structure, whereby the crystallinity of these nitride semiconductor single crystals can be further improved.

### EXAMPLES

Hereafter, the present invention will be described more particularly with reference to Examples. However, the present invention is not limited to the following Examples.

### Example 1

A Si (110) substrate was placed at a growth area in a reaction chamber, and then the Si (110) substrate was heated up to 1100° C. while supplying hydrogen as a career gas for the substrate cleaning.

Then, with the substrate temperature held, trimethyl aluminum (TMA) and ammonia were supplied as aluminum and nitrogen sources, respectively and a 2H—AlN buffer layer with a thickness of 10-500 nm was grown on the above-mentioned Si (110) substrate.

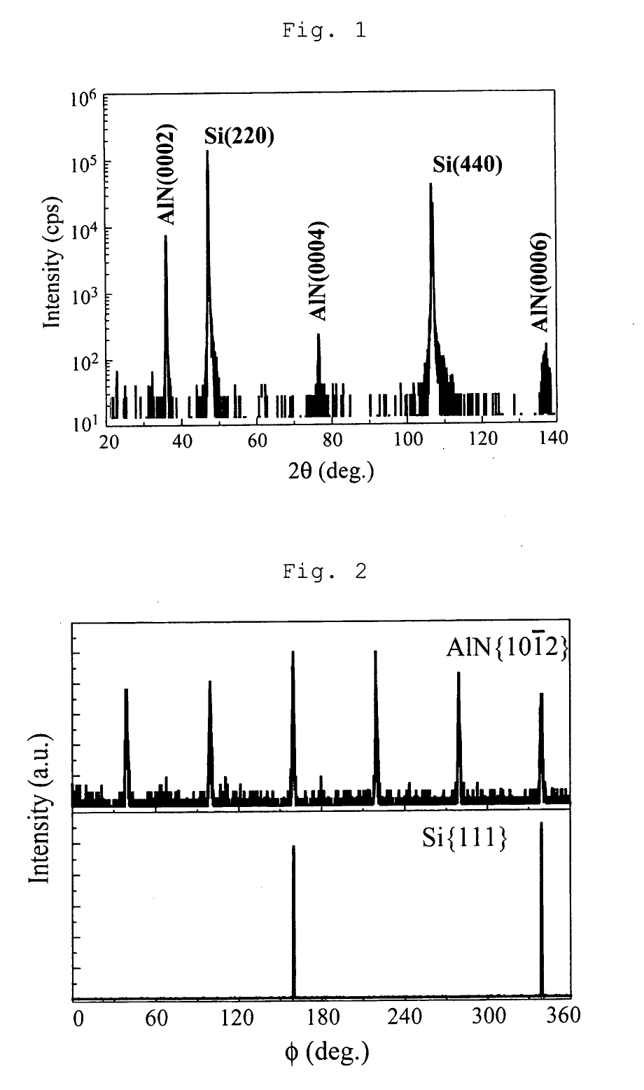

The 2H—AlN buffer layer grown on this Si (110) substrate was examined by θ-2θ scan and φ scan of X ray diffraction, and the orientations of the film in a growth direction (thickness direction) and in its plane were evaluated. These measured spectra are shown in FIGS. 1 and 2, respectively.

As shown in FIG. 1, it was confirmed that the growth direction <0001> of AlN film as the buffer layer was orientated with respect to the normal direction of Si (110) substrate.

Further, as shown in FIG. 2, in φ scan of X ray diffraction, symmetrical peaks were confirmed six times with respect to 2H—AlN, so that it was confirmed that there were no rotated 2H—AlN in the plane and the single crystal film is grown as a buffer layer.

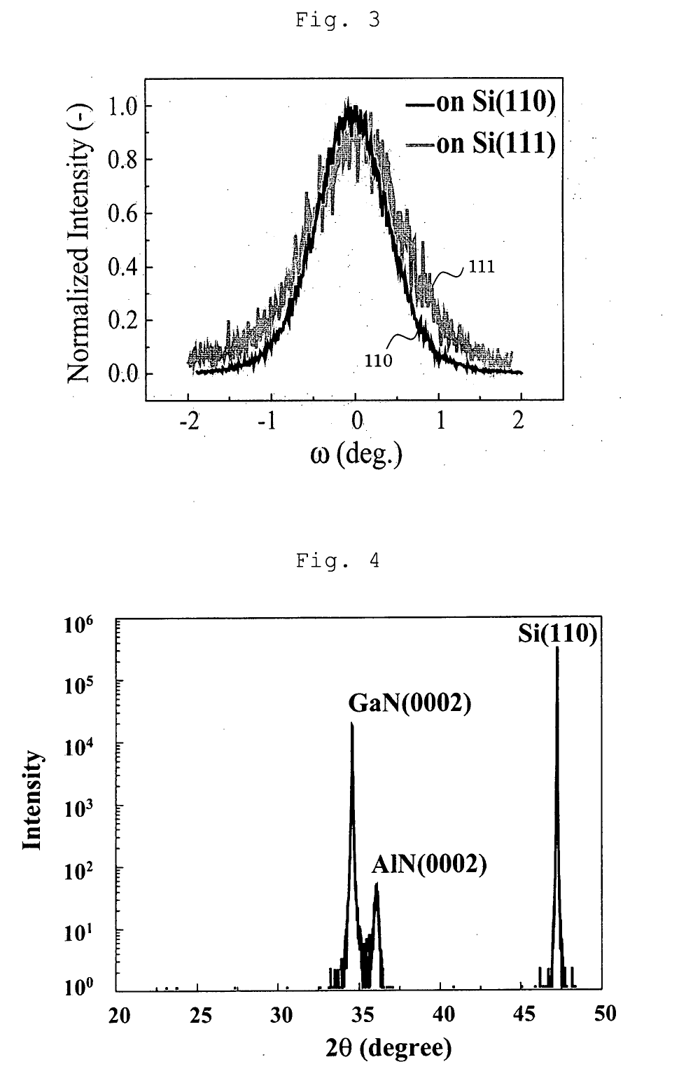

Further, ω scan of X ray diffraction was performed to investigate the crystallinity of 2H—AlN. The measured spectrum is shown in FIG. 3.

Next, the substrate temperature was lowered to approximately 1000° C., trimethyl gallium (TMG) and ammonia were supplied as gallium and nitrogen sources, respectively, and a GaN single crystal layer was grown on the above-mentioned 2H—AlN buffer layer.

When the above-mentioned GaN single crystal layer was grown with the thickness of one μm or more, any cracks were not observed.

Further, θ-2θ scan of X ray diffraction was performed with respect to the above-mentioned GaN single crystal layer, and the orientation of the crystal in the crystal growth direction (thickness direction) was investigated. The measured spectrum is shown in FIG. 4.

As shown in FIG. 4, it was confirmed that the GaN (0001) single crystal layer was grown on the 2H—AlN (0001) buffer layer.

### Example 2

As with Example 1, a 2H—AlN buffer layer was grown on a Si (110) substrate.

Then, a substrate temperature was increased to 1200° C. or more, TMA and ammonia were supplied as source materials, and an AlN (0001) single crystal layer was grown.

When the above-mentioned AlN (0001) single crystal layer was grown with the thickness of one μm or more, any cracks were not observed.

### Comparative Examples 1 and 2

A Si (111) substrate was used instead of the Si (110) substrate and other procedures were same to those in Examples 1 and 2. A GaN (0001) single crystal (Comparative Example 1) and an AlN (0001) single crystal (Comparative Example 2) were grown, resulting in a crack in the film.

Further, ω scan of X ray diffraction was performed with respect to a 2H—AlN buffer layer grown on the Si (111) substrate, to investigate the crystallinity of AlN. The measured spectrum is shown in FIG. 3 together with the spectrum at the case of using the above-mentioned the Si (110) substrate (Example 1).

As shown in FIG. 3, in ω scan of X ray diffraction, comparison of the full width at half maximum value of AlN on Si (110) and Si (111) shows that ones on Si (110) are smaller and have higher crystallinity.

Therefore, in proportion to the crystallinity of such a 2H—AlN buffer layer, the crystallinity of the GaN single crystal or an AlN single crystal layer grown on the buffer layer is also improved, and it can be said that Examples 1 and 2 provide higher crystallinity than Comparative Examples 1 and 2.

### Example 3

As with Example 1, a 2H—AlN buffer layer was grown on a Si (110) substrate. Then a substrate temperature was set to be 1000° C., TMG or TMA as a group III source and ammonia as a nitrogen source material were supplied to form 80 pairs of films where one pair films included the GaN (0001) single crystal layer with the thickness of 25 nm and the AlN (0001) single crystal layer with the thickness of 5 nm.

A GaN (0001) layer was grown thereon, and it was confirmed that a film could be grown with the thickness of two μm or more without a crack generation.

What is clamed is:

1. A nitride semiconductor single crystal grown on a Si (110) substrate with a 2H—AlN buffer layer and comprising GaN (0001) or AlN (0001).

2. A nitride semiconductor single crystal grown on a Si (110) substrate with a 2H—AlN buffer layer and a super-lattice structure of GaN (0001) and AlN (0001).
